(19) United States
(12) Patent Application Publication
(10) Pub. No.: US 2014/0291618 A1
(43) Pub. Date: Oct. 2, 2014

(54) METHOD OF MANUFACTURING ORGANIC LIGHT-EMITTING DISPLAY DEVICE AND ORGANIC LIGHT-EMITTING DISPLAY DEVICE

(71) Applicant: SAMSUNG DISPLAY CO., LTD., Yongin-City (KR)

(72) Inventors: Sang-Nam Na, Yongin-City (KR); Mu-Hyun Kim, Yongin-City (KR)

(73) Assignee: SAMSUNG DISPLAY COl., LTD., Yongin-city (KR)

(21) Appl. No.: 13/940,255

(22) Filed: Jul. 11, 2013

(30) Foreign Application Priority Data
Mar. 26, 2013 (KR) 10-2013-0032361

(51) Int. Cl. H01L 27/32; H01L 51/56

(52) U.S. Cl. CPC H01L 27/3248; H01L 51/56
USPC 257/40; 438/34

(57) ABSTRACT

A method of manufacturing an organic light-emitting display device, wherein a voltage drop of a counter electrode is effectively reduced, includes: (i) forming a layer on a substrate using a first deposition assembly, wherein the first deposition assembly includes a patterning slit sheet that includes patterning slits corresponding to sub-pixels emitting light in a first wavelength band from among n sub-pixels of each of pixels and does not include a patterning slit in regions corresponding to spaces between pixels in a second direction crossing a first direction and parallel to the substrate fixed to a transfer unit; and (ii) forming a layer on the substrate using a second deposition assembly, wherein the second deposition assembly includes a patterning slit sheet that includes patterning slits corresponding to the pixels and does not include a patterning slit in regions corresponding to spaces between the pixels in the second direction.

### CROSS-REFERENCE TO RELATED APPLICATION

This application claims priority to and the benefit of Korean Patent Application No. 10-2013-0032361, filed on Mar. 26, 2013, in the Korean Intellectual Property Office, the entire content of which is incorporated herein by reference.

### BACKGROUND

1. Field

Aspects of the present invention relate to a method of manufacturing an organic light-emitting display device and an organic light-emitting display device manufactured by the method.

2. Description of the Related Art

Organic light-emitting display devices have wider viewing angles, better contrast characteristics, and faster response speeds than other display devices, and thus have drawn attention as the next-generation display devices.

An organic light-emitting display device includes an intermediate layer including an emission layer between a first electrode and a second electrode that are arranged opposite to each other. Here, the first and second electrodes and the intermediate layer may be formed using any one of various suitable methods, such as an independent deposition method. When an organic light-emitting display device is manufactured by using a deposition method, a fine metal mask (FMM) having openings of the same/similar pattern as an intermediate layer to be formed is arranged to closely contact a substrate on which the intermediate layer and the like are to be formed, and an intermediate layer material is deposited on the FMM to form the intermediate layer having a desired pattern.

However, when an organic light-emitting display device having a large area is manufactured by using a large substrate or a plurality of organic light-emitting display devices are simultaneously manufactured by using a large mother-substrate by using a comparable deposition method using such an FMM, a large FMM has to be used. In this case, the FMM may bend due to gravity, and thus an intermediate layer having a pre-set accurate pattern may not be formed. Moreover, processes of aligning a large substrate and a large FMM to closely contact each other, performing deposition thereon, and separating the large FMM from the large substrate are time-consuming, resulting in a long manufacturing time and low production efficiency.

### SUMMARY

According to aspects of embodiments of the present invention, in a method of manufacturing organic light-emitting display devices, a voltage drop of a counter electrode is effectively reduced, and an organic light-emitting display device may be manufactured by the method.

Additional aspects will be set forth in part in the description which follows and, in part, will be apparent from the description, or may be learned by practice of the presented embodiments.

According to an embodiment of the present invention, a method of manufacturing an organic light-emitting display device including a plurality of pixels, each of the plurality of pixels including n sub-pixels, the organic light-emitting display device including an intermediate layer integrally formed throughout a plurality of sub-pixels in a first direction includes: conveying a transfer unit into a chamber by using a first conveyer unit configured to penetrate through the chamber, while a substrate is fixed to the transfer unit; forming a layer by depositing a deposition material discharged from a plurality of deposition assemblies while conveying one of the substrate or the plurality of deposition assemblies relative to the other by using the first conveyer unit, while the substrate is spaced apart from the plurality of deposition assemblies by a distance, the plurality of deposition assemblies being arranged in the chamber; and returning the transfer unit from which the substrate is separated, by using a second conveyer unit, wherein each of the plurality of deposition assemblies may include: a deposition source for discharging the deposition material; a deposition source nozzle unit of the deposition source arranged in a direction of the first conveyer unit and comprising a deposition source nozzle; and a patterning slit sheet facing the deposition source nozzle unit and including a plurality of patterning slits arranged along one direction; and the forming of the layer includes: forming a layer by depositing a deposition material discharged from a first deposition assembly on the substrate, wherein the first deposition assembly includes a patterning slit sheet that comprises patterning slits corresponding to sub-pixels emitting light in a first wavelength band from among the n sub-pixels of each of the plurality of pixels and does not comprise a patterning slit in regions corresponding to spaces between the plurality of pixels in a second direction crossing the first direction and parallel to the substrate fixed to the transfer unit; and forming a layer by depositing a deposition material discharged from a second deposition assembly on the substrate, wherein the second deposition assembly includes a patterning slit sheet that includes patterning slits corresponding to the plurality of pixels and does not include a patterning slit in regions corresponding to spaces between the plurality of pixels in the second direction.

According to another embodiment of the present invention, a method of manufacturing an organic light-emitting display device including a plurality of pixels, each of the plurality of pixels including n sub-pixels, the organic light-emitting display device including an intermediate layer integrally formed throughout a plurality of sub-pixels in a first direction includes: conveying a transfer unit into a chamber by using a first conveyer unit configured to penetrate through the chamber, while a substrate is fixed to the transfer unit; forming a layer by depositing a deposition material discharged from a plurality of deposition assemblies while conveying one of the substrate or the plurality of deposition assemblies relative to the other by using the first conveyer unit, while the substrate is spaced apart from the plurality of deposition assemblies by a distance, the plurality of deposition assemblies being arranged in the chamber; and returning the transfer unit from which the substrate is separated, by using a second conveyer unit, wherein each of the plurality of deposition assemblies includes: a deposition source for discharging the deposition material; a deposition source nozzle unit arranged in a direction of the first conveyer unit of the deposition source and comprising a deposition source nozzle; and a patterning slit sheet facing the deposition source nozzle unit and including a plurality of patterning slits arranged along one direction; and the forming of the layer includes: forming a layer by depositing a deposition material discharged from a first deposition assembly on the substrate, wherein the first deposition assembly includes a patterning slit sheet that comprises patterning slits corresponding to sub-pixels emitting light in a first wavelength band from among the n sub-pixels of each of the plurality of pixels and does not include a patterning slit in regions corresponding to spaces between the plurality of pixels in a second direction crossing the first direction and parallel to the substrate fixed to the transfer unit; and forming a layer by depositing a deposition material discharged from a second deposition assembly on the substrate, wherein the second deposition assembly includes a patterning slit sheet that includes patterning slits corresponding to the n sub-pixels of each of the plurality of pixels and does not include a patterning slit in regions corresponding to spaces between the plurality of pixels in the second direction and between the n sub-pixels in the second direction.

The one direction may be the second direction. The patterning slits may extend in the first direction.

According to another embodiment of the present invention, an organic light-emitting display device includes: a substrate; a plurality of thin-film transistors on the substrate; a plurality of pixel electrodes electrically connected to the plurality of thin-film transistors; a plurality of deposition layers on the plurality of pixel electrodes; and a counter electrode on the deposition layers, wherein at least two of the plurality of deposition layers have a linear pattern formed by using one of the methods above.

The organic light-emitting display device may include a plurality of pixels each including n sub-pixels, wherein sub-pixels emitting light in a same wavelength band may be arranged in a first direction, and the n sub-pixels of each of the plurality of pixels may be arranged in a second direction crossing the first direction.

The organic light-emitting display device may further include bus electrodes that are arranged between each of the plurality of pixels in the second direction, extend in the first direction, and are electrically connected to the counter electrode.

The deposition layers may include an emission layer, wherein layers of the deposition layers other than the emission layer may be integrally formed through the n sub-pixels of each of the plurality of pixels, may be integrally formed through the plurality of pixels in the first direction, and may not contact the bus electrodes.

The deposition layers may include an emission layer, wherein layers of the deposition layers other than the emission layer may not be formed between the n sub-pixels in the second direction of each of the plurality of pixels, may be integrally formed through sub-pixels emitting light in a same wavelength band in the first direction, and may not contact the bus electrodes.

The substrate may have a size equal to or larger than 40 inches.

### BRIEF DESCRIPTION OF THE DRAWINGS

The above and other features and advantages of the present invention will become more apparent by describing in more detail some example embodiments thereof with reference to the attached drawings in which:

FIG. 1 is a schematic plan view illustrating a deposition apparatus according to an embodiment of the present invention;

FIG. 2 is a schematic side view of a deposition unit of the deposition apparatus of FIG. 1, according to an embodiment of the present invention;

FIG. 3 is a schematic perspective cross-sectional view of a part of the deposition unit of the deposition apparatus of FIG. 1, according to an embodiment of the present invention;

FIG. 4 is a schematic cross-sectional view of a part of the deposition unit of the deposition apparatus of FIG. 1, according to an embodiment of the present invention;

FIG. 5 is a schematic plan view of a part of an organic light-emitting display device manufactured by using a deposition apparatus, according to an embodiment of the present invention;

FIG. 6 is a schematic perspective view of a substrate and a patterning slit sheet of a first deposition assembly in the deposition unit of the deposition apparatus of FIG. 1, according to an embodiment of the present invention;

FIG. 7 is a schematic perspective view of a substrate and a patterning slit sheet of a second deposition assembly in the deposition unit of the deposition apparatus of FIG. 1, according to an embodiment of the present invention;

FIG. 8 is a schematic cross-sectional view of an organic light-emitting display device manufactured by using a deposition apparatus, according to an embodiment of the present invention; and

FIG. 9 is a schematic perspective view of a part of a deposition assembly of a deposition apparatus according to another embodiment of the present invention.

### DETAILED DESCRIPTION

Hereinafter, the present invention will be described more fully with reference to the accompanying drawings, in which some example embodiments of the invention are shown. The invention may, however, be embodied in many different forms and should not be construed as being limited to the embodiments set forth herein; rather, these embodiments are provided so that this disclosure will be thorough and complete. In the drawings, like reference numerals denote like elements, and the sizes and thicknesses of layers and regions may be exaggerated for clarity. For example, sizes and thicknesses of components may be arbitrarily illustrated for convenience of description, and thus are not limited thereto. As used herein, the term “and/or” includes any and all combinations of one or more of the associated listed items. Expressions such as “at least one of,” when preceding a list of elements, modify the entire list of elements and do not modify the individual elements of the list.

In one or more embodiments, below, x-, y-, and z-axes are not limited to three axes on rectangular coordinates, and may be interpreted in broader meanings including the three axes. For example, the x-, y-, and z-axes may cross each other at right angles, or may denote other directions that do not cross each other at right angles.

It will also be understood that when component, such as a layer, a film, a region, or a plate, is referred to as being “on” another component, it can be directly on the other component, or an intervening component may also be present.

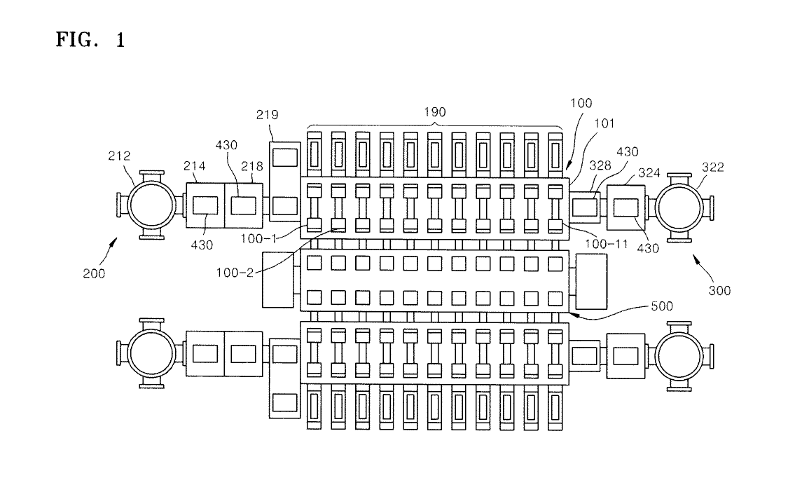

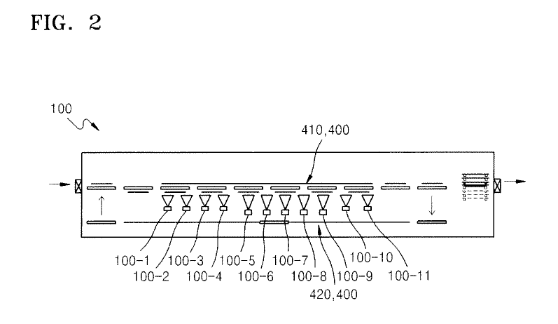

FIG. 1 is a schematic plan view illustrating a deposition apparatus according to an embodiment of the present invention, and FIG. 2 is a schematic side view of a deposition unit 100 of the deposition apparatus of FIG. 1, according to an embodiment of the present invention.

Referring to FIGS. 1 and 2, the deposition apparatus includes the deposition unit 100, a loading unit 200, an unloading unit 300, a conveyer unit 400, and a patterning slit sheet replacement unit 500. The conveyer unit 400 may include a first conveyer unit 410 capable of conveying a transfer unit 430 to which a substrate 2 is detachably fixed in a first direction, and a second conveyer unit 420 capable of conveying the transfer unit 430 separated from the substrate 2 in an opposite direction of the first direction.

The loading unit 200 may include a first rack 212, a transport chamber 214, a first inversion chamber 218, and a buffer chamber 219.

A plurality of the substrates 2 onto which a deposition material has not yet been deposited are stacked in the first rack 212. A transport robot picks up and holds the substrate 2 from the first rack 212, and disposes the substrate 2 on the transfer unit 430 conveyed by the second conveyer unit 420 and located in the transport chamber 214. The substrate 2 may be fixed to the transfer unit 430 by a clamp or the like, and the transfer unit 430 to which the substrate 2 is fixed is moved to the first inversion chamber 218. Before fixing the substrate 2 to the transfer unit 430, the substrate 2 may be aligned with respect to the transfer unit 430 if required.

In the first inversion chamber 218 adjacent to the transport chamber 214, a first inversion robot inverts the transfer unit 430. Accordingly, the transport robot places the substrate 2 on a top surface of the transfer unit 430, the transfer unit 430 is conveyed to the first inversion chamber 218 while a surface of the substrate 2 opposite to a surface in a direction of the transfer unit 430 faces upward, and as the first inversion robot inverts the first inversion chamber 218, the surface of the substrate 2 opposite to the surface in the direction of the transfer unit 430 faces downward. Then, the first conveyer unit 410 conveys the transfer unit 430 to which the substrate 2 is fixed.

The unloading unit 300 is configured to operate in an opposite manner to the loading unit 200 described above. Specifically, a second inversion robot in a second inversion chamber 328 inverts the substrate 2 and the transfer unit 430, which have passed through the deposition unit 100, and then conveys the substrate 2 and the transfer unit 430 to an ejection chamber 324. Then, the substrate 2 is separated from the transfer unit 430 in the ejection chamber 324, and an ejection robot stacks the separated substrate 2 in a second rack 322. The second conveyer unit 420 conveys the transfer unit 430 separated from the substrate 2 to the loading unit 200.

However, an embodiment of the present invention is not limited thereto, and the substrate 2 may be fixed to a bottom surface of the transfer unit 430 when initially fixed to the transfer unit 430 and may be conveyed in this manner. In such an embodiment, for example, the second inversion robot of the first inversion chamber 218 and the second inversion robot of the second inversion chamber 328 may not be required. Alternatively, the first and second inversion robots may invert only the transfer unit 430 to which the substrate 2 is fixed in the first or second inversion chamber 218 or 328, instead of inverting the first or second inversion chamber 218 or 328. Here, a conveyer unit in an inversion chamber may rotate by 180° while the transfer unit 430 is located on the conveyer unit in the inversion chamber capable of conveying the transfer unit 430 to which the substrate 2 is fixed, and at this time, the conveyer unit may operate as a first or second inversion robot. Here, the conveyer unit may be a part of the first or second conveyer unit 410 or 420.

The deposition unit 100 includes a chamber 101 as shown in FIGS. 1 and 2, and a plurality of deposition assemblies 100-1 through 100-n may be arranged in the chamber 101. In FIG. 1, eleven deposition assemblies, i.e., the deposition assemblies 100-1 through 100-11, are arranged in the chamber 101, but the number of deposition assemblies may vary according to a deposition material and a deposition condition. The chamber 101 may be in a vacuum or a near-vacuum state when deposition is performed.

The first conveyer unit 410 conveys the transfer unit 430 to which the substrate 2 is fixed to at least the deposition unit 100, in more detail, sequentially to the loading unit 200, the deposition unit 100, and the unloading unit 300, and the second conveyer unit 420 returns the transfer unit 430 separated from the substrate 2 in the unloading unit 300 to the loading unit 200. Accordingly, the transfer unit 430 may be cyclically conveyed by the first and second conveyer units 410 and 420.

The first conveyer unit 410 may be arranged to pass through the chamber 101 while passing through the deposition unit 100, and the second conveyer unit 420 may be arranged to convey the transfer unit 430 separated from the substrate 2.

Here, the first and second conveyer units 410 and 420 may be arranged above and below each other. Accordingly, after the transfer unit 430 on which the substrate 2 is attached and configured to be deposited on while passing through the first conveyer unit 410 is separated from the substrate 2 in the unloading unit 300, the transfer unit 430 is returned to the loading unit 200 through the second conveyer unit 420 arranged below the first conveyer unit 410, thereby improving space utilization efficiency. Alternatively, the second conveyer unit 420 may be arranged above the first conveyer unit 410.

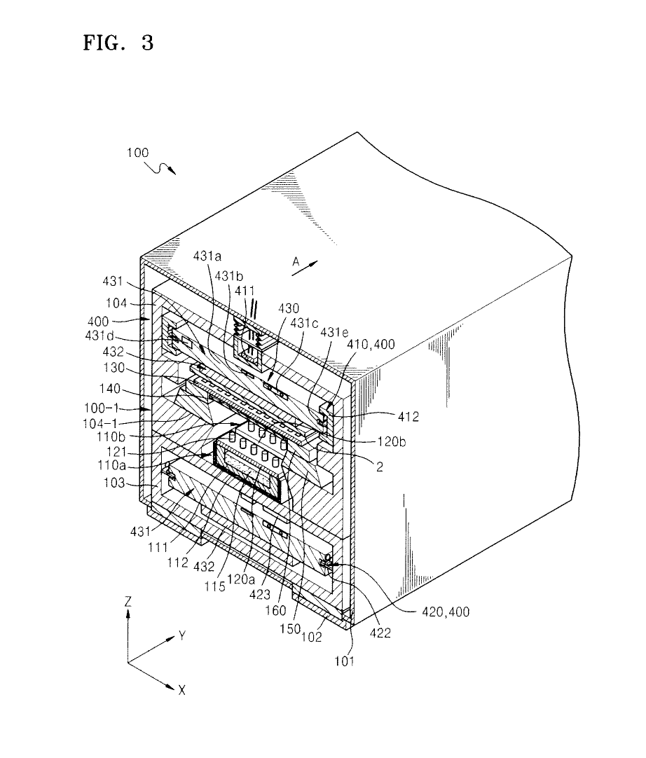

Meanwhile, as shown in FIG. 1, the deposition unit 100 may include a deposition source replacement unit 190 arranged at one side of each of the deposition assemblies 100-1 through 100-11. Although not shown in detail, the deposition source replacement unit 190 may have a cassette shape so as to be externally withdrawn from each of the deposition assemblies 100-1 through 100-11. As such, the first and second deposition sources 110a and 110b (shown in FIG. 3) of the deposition assembly 100-1 may be easily replaced.

In addition, in FIG. 1, two deposition apparatuses including the loading unit 200, the deposition unit 100, the unloading unit 300, and the conveyer unit 400 are arranged parallel to each other. In this case, the patterning slit sheet replacement unit 500 may be arranged between the two deposition apparatuses. In other words, the deposition apparatuses commonly use the patterning slit sheet replacement unit 500 so as to improve space utilization efficiency compared to when the deposition apparatuses each include the patterning slit sheet replacement unit 500.

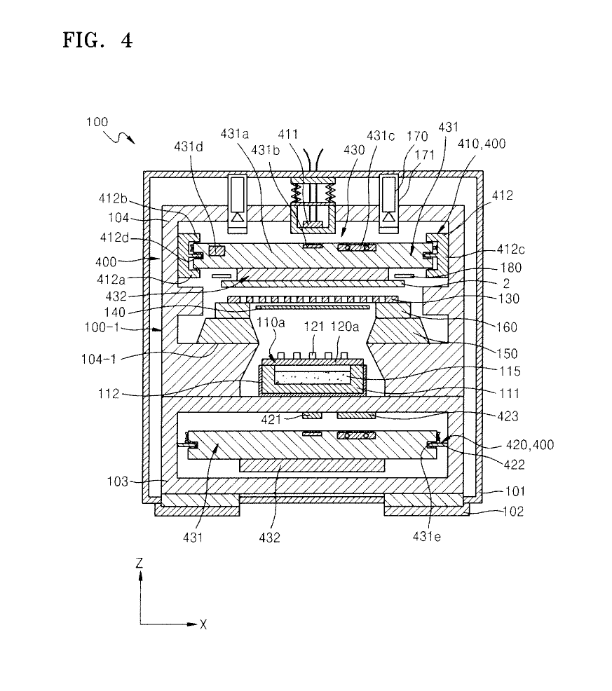

FIG. 3 is a schematic perspective cross-sectional view of a part of the deposition unit 100 of the deposition apparatus of FIG. 1, according to an embodiment of the present invention, and FIG. 4 is a schematic cross-sectional view of a part of the deposition unit 100 of the deposition apparatus of FIG. 1, according to an embodiment of the present invention. Referring to FIGS. 3 and 4, the deposition unit 100 of the deposition apparatus includes the chamber 101 and a plurality of deposition assemblies. For convenience of illustration, FIGS. 3 and 4 only show the deposition assembly 100-1.

The chamber 101 has an empty box shape, and accommodates one or more deposition assemblies 100-1 therein. As shown in FIGS. 3 and 4, the conveyer unit 400 may also be accommodated in the chamber 101, or extend inside and outside of the chamber 101 according to circumstances.

A lower housing 103 and an upper housing 104 may be accommodated in the chamber 101. In more detail, the lower housing 103 may be arranged on a foot 102 fixable to the ground, and the upper housing 104 may be arranged on the lower housing 103. Here, a connection part of the lower housing 103 and the chamber 101 may be sealed so that the inside of the chamber 101 is completely blocked from the outside. As such, by disposing the lower housing 103 and the upper housing 104 on the foot 102 fixed to the ground, the lower housing 103 and the upper housing 104 may maintain fixed locations even if the chamber 101 is repeatedly contracted and expanded. Accordingly, the lower housing 103 and the upper housing 104 may serve as a reference frame in the deposition unit 100.

The deposition assembly 100-1 and the first conveyer unit 410 of the conveyer unit 400 may be arranged inside the upper housing 104 and the second conveyer unit 420 of the conveyer unit 400 may be arranged inside the lower housing 103. The transfer unit 430 is cyclically conveyed by the first and second conveyer units 410 and 420 so that a deposition process is continuously performed on the substrate 2 fixed to the transfer unit 430. The transfer unit 430 that is cyclically conveyed as such may include a carrier 431 and an electrostatic chuck 432 combined to the carrier 431.

The carrier 431 may include a body unit 431a, a magnetic rail 431b, a contactless power supply (CPS) module 431c, a power supply unit 431d, and a guide groove 431e. If required, the carrier 431 may further include a cam follower.

The body unit 431 a constitutes a base unit of the carrier 431, and may be formed of a magnetic material, such as iron. The carrier 431 may be spaced apart from a guide unit 412 of the first conveyer unit 410 by a set or predetermined distance according to attraction force or repulsion force between the body unit 431a and a magnetically suspended bearing included in the first conveyer unit 410. In addition, the guide groove 431e may be formed on both side surfaces of the body unit 431a. A guide protrusion 412d of the guide unit 412 of the first conveyer unit 410 or a roller guide 422 of the second conveyer unit 420 may be accommodated in the guide groove 431 e.

In addition, the body unit 431a may include the magnetic rail 431b arranged along a centerline in a proceeding direction (e.g., Y-axis direction). The magnetic rail 431 b of the body unit 431 a may form a linear motor with a coil 411 of the first conveyer unit 410, and the carrier 431, i.e., the transfer unit 430 may be conveyed in direction indicated by an arrow A by the linear motor. Accordingly, the transfer unit 430 may be conveyed by a current supplied to the coil 411 of the first conveyer unit 410 without having to separately supply power to the transfer unit 430. Thus, a plurality of the coils 411 may be arranged at intervals (e.g., regular intervals) along the Y-axis direction in the chamber 101. The coil 411 may be provided in an atmospheric state since it is arranged in an atmosphere box.

Meanwhile, the body unit 431a may include the CPS module 431c and the power supply unit 431d respectively arranged at one side and the other side of the magnetic rail 431 b. The power supply unit 431 d includes a type of a chargeable battery for supplying power so that the electrostatic chuck 432 chucks the substrate 2 and maintains the chucking. The CPU module 431c is a wireless charging module for charging the chargeable battery of the power supply unit 431d. A charging track 423 included in the second conveyer unit 420 is connected to an inverter, and thus when the carrier 431 is conveyed by the second conveyer unit 420, a magnetic field is formed between the charging track 423 and the CPS module 431c, thereby supplying power to the CPS module 431c and charging the power supply unit 431d.

The electrostatic chuck 432 may include a body formed of ceramic, and an electrode embedded in the body and to which power is supplied. The substrate 2 is attached onto a surface of the body of the electrostatic chuck 432 as a high voltage is applied to the electrode embedded in the body from the power supply unit 431d in the body unit 431a of the carrier 431.

The first conveyer unit 410 may convey the transfer unit 430 having such a structure and to which the substrate 2 is fixed in a first direction (e.g., +Y-direction). The first conveyer unit 410 includes the coil 411 and the guide unit 412 described above, and may further include a magnetically suspended bearing or a gap sensor.

The coil 411 and the guide unit 412 may be each arranged on an inner surface of the upper housing 104, and for example, the coil 411 may be arranged on an upper inner surface of the upper housing 104 and the guide unit 412 may be arranged on both sides of the inner surfaces of the upper housing 104.

As described above, the coil 411 may form a linear motor with the magnetic rail 431b of the body unit 431a of the transfer unit 430 so as to move the transfer unit 430. The guide unit 412 may guide the transfer unit 430 so that the transfer unit 430 is conveyed in the first direction (e.g., Y-axis direction). The guide unit 412 may pass through the deposition unit 100.

In more detail, the guide unit 412 may accommodate two sides of the carrier 431 of the transfer unit 430 so as to guide the carrier 431 to move along the direction indicated by the arrow A of FIG. 3. Accordingly, the guide unit 412 may include a first accommodation unit 412a arranged below the carrier 431, a second accommodation unit 412b arranged above the carrier 431, and a connection unit 412c connecting the first and second accommodation units 412a and 412b. An accommodation groove may be formed by the first accommodation unit 412a, the second accommodation unit 412c, and the connection unit 412c, and the guide unit 412 may have the guide protrusion 412d in the accommodation groove.

A magnetically suspended bearing may be arranged in the connection unit 412c of the guide unit 412 so as to correspond to two side surfaces of the carrier 431. The magnetically suspended bearing generates an interval between the carrier 431 and the guide unit 412 so that the carrier 431 is conveyed along the guide unit 412 in a non-contact manner without contacting the guide unit 412. The magnetically suspended bearing may also be arranged in the second accommodation unit 412b of the guide unit 412 to be located on the carrier 431. In this case, the magnetically suspended bearing may enable the carrier 431 to move along the guide unit 412 while maintaining a set or predetermined interval from the first or second accommodation unit 412a or 412b without contacting it. In order to check an interval between the carrier 431 and the guide unit 412, the guide unit 412 may include a gap sensor arranged in the first accommodation unit 412a and/or the connection unit 412c so as to correspond to the bottom of the carrier 431. Magnetic force of the magnetically suspended bearing is changed according to a value measured by the gap sensor, and thus the interval between the carrier 431 and the guide unit 412 may be adjusted in real-time. In other words, the carrier 431 may be precisely conveyed according to feedback-control using the magnetically suspended bearing and the gap sensor.

After a deposition process is completed as the substrate 2 passes through the deposition unit 100, the second conveyer unit 420 returns the transfer unit 430 from which the substrate 2 is separated in the unloading unit 300 to the loading unit 200. In one embodiment, the second conveyer unit 420 may include a coil 421, the roller guide 422, and the charging track 423 described above, which are arranged in the lower housing 103. For example, the coil 421 and the charging track 423 may be arranged on an upper inner surface of the lower housing 103, and the roller guide 422 may be arranged on both inner surfaces of the lower housing 103. Here, although not illustrated, the coil 421 may be arranged in an atmosphere box like the coil 411 of the first conveyer unit 410.

Like the coil 411, the coil 421 may form a linear motor with the magnetic rail 431 b of the carrier 431 of the transfer unit 430. The transfer unit 430 may be conveyed in an opposite direction (e.g., −Y direction) of the first direction (e.g., +Y direction) by the linear motor.

The roller guide 422 guides the carrier 431 to move in the opposite direction of the first direction. The roller guide 422 may be arranged to penetrate through the deposition unit 100. The roller guide 422 supports cam followers respectively arranged on two sides of the carrier 431 of the transfer unit 430 so as to guide the transfer unit 430 to be conveyed in the opposite direction of the first direction.

Since the second conveyer unit 420 returns the transfer unit 430 separated from the substrate 2 to the loading unit 200, location precision of the transfer unit 430 being conveyed is not largely required compared to the first conveyer unit 410 that conveys the transfer unit 430 to which the substrate 2 is fixed so that a deposition process is performed on the substrate 2. Accordingly, a magnetically suspending function may be applied to the first conveyer unit 410 that requires high location precision of the transfer unit 430 so as to obtain high location precision of the transfer unit 430, and a general roller method may be applied to the second conveyer unit 420 so as to simplify a structure of the deposition apparatus and reduce manufacturing costs of the deposition apparatus. However, if required, a magnetically suspending function may also be applied to the second conveyer unit 420.

While the first conveyer unit 410 conveys the substrate 2 fixed to the transfer unit 430 in the first direction (e.g., +Y direction), the deposition assembly 100-1 deposits a material on the substrate 2 by being spaced apart from the substrate 2. A more detailed structure of the deposition assembly 100-1 will now be described.

The deposition assembly 100-1 may include the first and second deposition sources 110a and 110b, first and second deposition source nozzle units 120a and 120b, a patterning slit sheet 130, a shielding member 140, a first stage 150, a second stage 160, a camera 170, and a sensor 180. Here, most components shown in FIGS. 3 and 4 may be arranged in the chamber 101 that maintains an appropriate vacuum level so as to obtain linearity of a deposition material.

The first and second deposition sources 110a and 110b may discharge a deposition material. The deposition assembly 100-1 of the deposition apparatus according to the current embodiment includes the first and second deposition sources 110a and 110b that are arranged in the first direction to sequentially approach the substrate 2 while the first conveyer unit 410 conveys the substrate 2 fixed to the transfer unit 430. However, three or more deposition sources may be included in the deposition assembly 100-1. Alternatively, only one deposition source may be included in the deposition assembly 100-1. For convenience of description, the deposition assembly 100-1 includes the first and second deposition sources 110a and 110b.

The first and second deposition sources 110a and 110b may be arranged at the bottom of the deposition assembly 100-1 so as to discharge a deposition material 115 contained in the first and second deposition sources 110a and 110b towards a direction (for example, +Z direction) where the substrate 2 is located, as the deposition material 115 is sublimated/evaporated. In more detail, the first and second deposition sources 110a and 110b may each include a crucible 111 in which the deposition material 115 is filled, and a heater 112 for heating the crucible 111 to evaporate the deposition material 115 filled in the crucible 111.

The first and second deposition source nozzle units 120a and 120b including deposition source nozzles 121 of the first and second deposition sources 110a and 110b are arranged in a direction (e.g., +Z direction) of the first conveyer unit 410, i.e., in a direction of the substrate 2. In more detail, the first deposition source nozzle unit 120a of the first deposition source 110a is arranged in the direction of the first conveyer unit 410, and the second deposition source nozzle unit 120b of the second deposition source 110b is arranged in the direction of the first conveyer unit 410. In the drawings, the first and second deposition source nozzle units 120a and 120b include a plurality of the deposition source nozzles 121.

In the drawings, the first and second deposition source nozzle units 120a and 120b are separated from each other, but an embodiment of the present invention is not limited thereto. For example, the first and second deposition sources 110a and 110b may be accommodated in one container having an opened top, and one deposition source nozzle unit including deposition source nozzles corresponding to the first deposition source 110a and deposition source nozzles corresponding to the second deposition source 110b may be located on the container. In other words, the first and second deposition source nozzles units 120a and 120b may be integrally formed. Hereinafter, for convenience of description, the first and second deposition source nozzle units 120a and 120b are separated from each other.

The patterning slit sheet 130 may be arranged to face the first and second deposition source nozzle units 120a and 120b, and may include a plurality of patterning slits along one direction. Here, the one direction may be a second direction (e.g., X-axis direction) crossing the first direction (e.g., Y-axis direction) and parallel to the substrate 2 fixed to the transfer unit 430. The patterning slit sheet 130 is arranged between the first and second deposition sources 110a and 110b, and the substrate 2. The deposition materials 115 evaporated from the first and second deposition sources 110a and 110b may pass through the first and second deposition source nozzle units 120a and 120b and the patterning slit sheet 130, and be deposited on the substrate 2 that is a target for the deposition material.

The patterning slit sheet 130 may be manufactured via etching, or the like, which is used in a comparable method of manufacturing a fine metal mask (FMM), specifically a stripe type mask. The patterning slit sheet 130 may be spaced apart from the first and second deposition sources 110a and 110b (and the first and second deposition source nozzle units 120a and 120b combined thereto) by a set or predetermined distance.

In order for the deposition material 115 discharged from the first and second deposition sources 110a and 110b to be deposited on the substrate 2 in a desired pattern, through the first and second deposition source nozzle units 120a and 120b and the patterning slit sheet 130, the inside of a chamber basically needs to maintain a high vacuum state as in FMM deposition. Also, a temperature of the patterning slit sheet 130 may be sufficiently lower than temperatures of the first and second deposition sources 110a and 110b, i.e., lower than or equal to about 100° C. The temperature of the patterning slit sheet 130 may be sufficiently low so as to prevent or substantially prevent thermal expansion of the patterning slit sheet 130 caused by high temperature. In other words, when the temperature of the patterning slit sheet 130 is increased, sizes or locations of patterning slits of the patterning slit sheet 130 are changed due to thermal expansion, and thus the deposition material 115 may be deposited on the substrate 2 in a pattern different from a set or predetermined pattern.

The substrate 2 that is a target for deposition material is arranged in the chamber 101. The substrate 2 may be a substrate for a flat panel display apparatus, and may be a large substrate, such as a mother glass, for forming a plurality of flat panel display apparatuses.

As described above, according to a general deposition method using an FMM, an area of the FMM is equal to an area of a substrate. Accordingly, when a size of the substrate is increased, a size of the FMM is also increased, and thus it is not easy to manufacture the FMM. Moreover, since the FMM may bend due to gravity, an intermediate layer having a set or predetermined pattern may not be accurately formed.

However, according to the deposition apparatus of the current embodiment, a deposition process is performed as the deposition assembly 100-1 and the substrate 2 move relatively to each other. In more detail, while the first conveyer unit 410 conveys the substrate 2 fixed to the transfer unit 430 in the first direction (e.g., +Y direction), the deposition assembly 100-1 spaced apart from the substrate 2 by a set or predetermined distance deposits a material on the substrate 2. In other words, the deposition process is performed in a scanning manner as the substrate 2 facing the deposition assembly 100-1 is conveyed in the direction indicated by the arrow A of FIG. 3. Here, the deposition process is performed as the substrate 2 moves in the +Y direction in the chamber 101, but an embodiment of the present invention is not limited thereto. For example, the location of the substrate 2 may be fixed and the deposition process may be performed as the deposition assembly 100-1 moves in the −Y direction.

Thus, in the deposition apparatus of the current embodiment, the size of the patterning slit sheet 130 may be much smaller than a size of a general FMM. In other words, since the deposition process is continuously performed, i.e., in a scanning manner as the substrate 2 moves along the Y-axis direction, the deposition process may be sufficiently performed on an entire surface of the substrate 2 even if the length of the Y-axis direction of the patterning slit sheet 130 is much shorter than the length of the Y-axis direction of the substrate 2.

As such, since the size of the patterning slit sheet 130 may be much smaller than the size of the general FMM, the patterning slit sheet 130 may be easily manufactured. In other words, the patterning slit sheet 130 having a small size is more advantageous in all the manufacturing processes, including an etching process followed by precise elongation, welding, transferring, and washing processes, than the FMM used in a general deposition method. In addition, the patterning slit sheet 130 is more advantageous for manufacturing a large display device.

As described above, the deposition assembly 100-1 deposits a material on the substrate 2 by being spaced apart from the substrate 2, while the first conveyer unit 410 conveys the substrate 2 fixed to the transfer unit 430 in the first direction (e.g., +Y direction). This means that the patterning slit sheet 130 is spaced apart from the substrate 2 by a set or predetermined distance. According to a general deposition apparatus using an FMM, a defective product may be generated as the FMM and a substrate contact each other, but the deposition apparatus according to embodiments of the present invention may effectively prevent or substantially prevent a defective product. Also, since a time required to adhere a substrate and a mask is not required, a manufacturing speed may be remarkably increased.

The upper housing 104 may include an accommodation unit 104-1 protruding from both sides of the first and second deposition sources 110a and 110b, and both sides of the first and second deposition source nozzles 120a and 120b. The first and second stages 150 and 160 may be arranged on the accommodation unit 104-1, and the patterning slit sheet 130 may be arranged on the second stage 160.

The first stage 150 may adjust a location of the patterning slit sheet 130 in the X-axis direction and the Y-axis direction. In other words, the first stage 150 may include a plurality of actuators to move the location of the patterning slit sheet 130 in the X- and Y-axis directions with respect to the upper housing 104. The second stage 160 may adjust the location of the patterning slit sheet 130 in the Z-axis direction. For example, the second stage 160 may include an actuator to move the location of the patterning slit sheet 130 along the Z-axis direction with respect to the first stage 150 and the upper housing 104.

As such, by adjusting the location of the patterning slit sheet 130 with respect to the substrate 2 by using the first and second stages 150 and 160, the substrate 2 and the patterning slit sheet 130 may be aligned, specifically in real-time.

In addition, the upper housing 104, the first stage 150, and the second stage 160 may simultaneously guide a moving path of the deposition material 115 so that the deposition material 115 discharged from the deposition source nozzle 121 is not dispersed. In other words, the moving path of the deposition material 115 is limited by the upper housing 104, the first stage 150, and the second stage 160, so as to limit the movement of the deposition material 115 in the X-axis direction.

Meanwhile, the deposition assembly 100-1 may further include the camera 170 and the sensor 180 for alignment. The sensor 180 may be a confocal sensor. The camera 170 may generate data for accurately aligning the pattering slit sheet 130 and the substrate 2 on an XY plane by checking a first mark formed on the patterning slit sheet 130 and a second mark formed on the substrate 2 in real-time, and the sensor 180 may generate data about an interval between the patterning slit sheet 130 and the substrate 2 so as to maintain a suitable interval.

As such, by using the camera 170 and the sensor 180, the interval between the substrate 2 and the patterning slit sheet 130 may be measured in real-time, and thus the substrate 2 and the patterning slit sheet 130 may be aligned in real-time. Accordingly, location precision of a pattern may be further improved.

Meanwhile, the shielding member 140 may be arranged between the patterning slit sheet 130 and the first and second deposition sources 110a and 110b so as to prevent a material from being deposited in a non-film-forming region of the substrate 2. Although not shown in detail, the shielding member 140 may include two neighboring plates. By covering the non-film-forming region of the substrate 2 by the shielding member 140, the non-film-forming region may be conveniently and effectively prevented from being deposited by a material without having to use a separate structure.

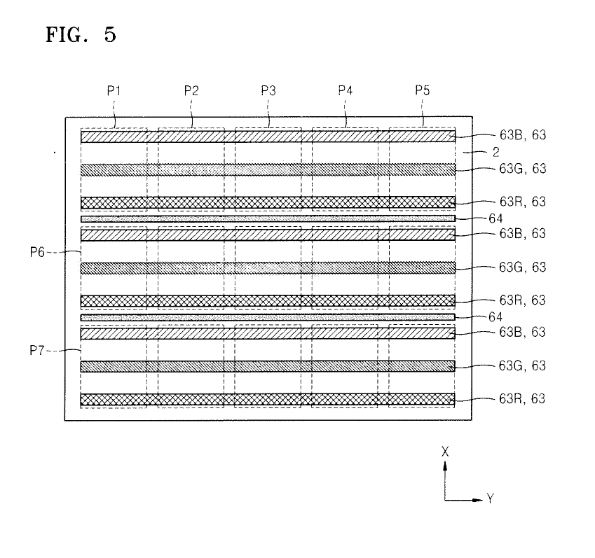

FIG. 5 is a schematic plan view of a part of an organic light-emitting display device manufactured by using a deposition apparatus, such as the deposition apparatus of FIG. 1, according to an embodiment of the present invention. As shown in FIG. 5, a plurality of pixels P1 through P7 are formed on the substrate 2, wherein each of the pixels P1 through P7 may include n sub-pixels. For example, in FIG. 5, each of the pixels P1 through P7 includes 3 sub-pixels, i.e., a red sub-pixel, a green sub-pixel, and a blue sub-pixel. Hereinafter, for convenience of description, one pixel includes three sub-pixels.

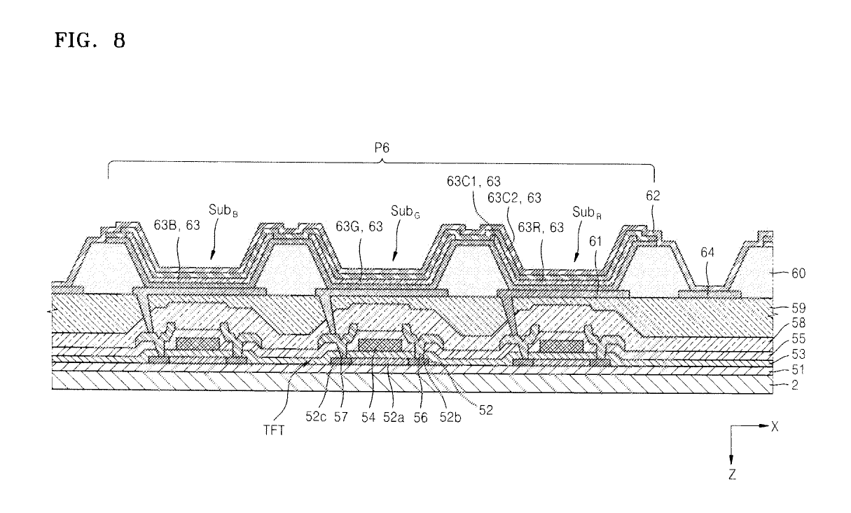

In the organic light-emitting display device, an organic light-emitting diode (OLED) is formed in each sub-pixel, wherein the OLED includes a pixel electrode 61, a counter electrode 62 facing the pixel electrode 61, and an intermediate layer 63 between the pixel electrode 61 and the counter electrode 62 and including an emission layer, as shown in FIG. 8. The pixel electrodes 61 are patterned to be spaced apart from each other according to sub-pixels, and the counter electrodes 62 are integrated with respect to the pixels P1 through P7. Further details thereof are described later.

The emission layer of the intermediate layer 63 may be patterned. In more detail, as shown in FIG. 5, a red emission layer 63R, a green emission layer 63G, and a blue emission layer 63B are patterned to be spaced apart from each other. Moreover, the red emission layers 63R are integrated throughout the pixels P1 through P5 along a direction (e.g., Y-axis direction), the green emission layers 63G are also integrated throughout the pixels P1 through P5 along the direction (e.g., Y-axis direction), and the blue emission layers 63B are also integrated throughout the pixels P1 through P5 along the direction (e.g., Y-axis direction). This is because as described above, the red, green, and/or blue emission layers 63R, 63G, and/or 63B are deposited as the substrate 2 moves along the direction (e.g., Y-axis direction) while the deposition assembly 100-1 and the substrate 2 are spaced apart from each other by the set or predetermined distance.

Meanwhile, the organic light-emitting display device may include a bus electrode 64 between two adjacent pixels (for example, the pixels P1 and P6) in a direction (e.g., X-axis direction), and the bus electrode 64 may be elongated in the direction (e.g., Y-axis direction) crossing that direction as shown in FIG. 5. The bus electrodes 64 may contact the counter electrodes 62 so as to reduce voltage drop of the counter electrode 62. Accordingly, the intermediate layer 63 may not be formed between the bus electrode 64 and the counter electrode 62. In other words, when the intermediate layer 63 is formed on the bus electrode 64, the bus electrode 64 may not contact the counter electrode 62, and thus is unable to reduce the voltage drop of the counter electrode 62.

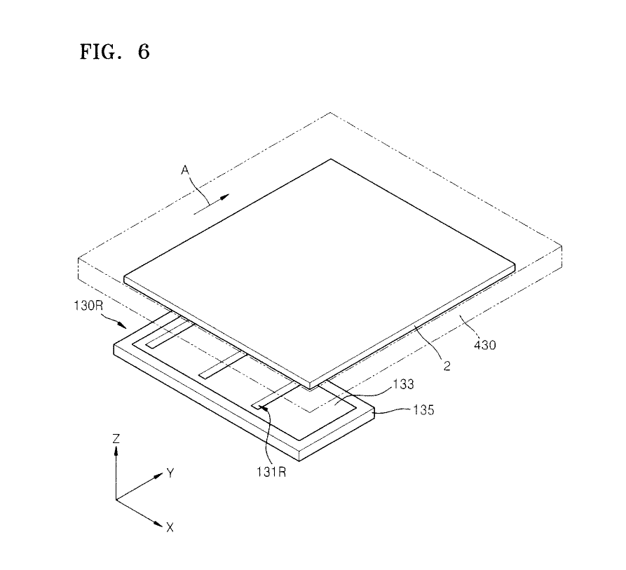

Accordingly, a patterning slit sheet 130R shown in FIG. 6 may be used while depositing the emission layer of the intermediate layer 63. In more detail, FIG. 6 is a schematic perspective view of the substrate 2 on which a deposition material is deposited and the patterning slit sheet 130R of a first deposition assembly from among a plurality of deposition assemblies in the deposition unit 100 of the deposition apparatus of FIG. 1, according to an embodiment of the present invention. The first deposition assembly may be used to deposit the red emission layer 63R on the substrate 2.

The patterning slit sheet 130R of the first deposition assembly may have a structure in which a sheet 133 having patterning slits 131R corresponding to sub-pixels emitting light in a first wavelength band of red light from among three sub-pixels of each of the pixels is combined to a frame 135 having an approximate window frame via welding, or the like. The patterning slit sheet 130R does not include a pattering slit in a region corresponding to a space between pixels. In more detail, the pattering slit sheet 130R does not include a patterning slit in a region corresponding to a space between pixels in the second direction (e.g., X-axis direction) crossing the first direction (e.g., Y-axis direction) and parallel to the substrate 2 fixed to the transfer unit 430. Since the patterning slit 131R of the patterning slit sheet 130R is extended in the first direction, the patterning slit sheet 130R may have an opening corresponding to a region between the pixels P4 and P5 shown in FIG. 5 in the first direction.

When the first conveyer unit 410 conveys the transfer unit 430 to which the substrate 2 is fixed in one direction (e.g., +Y direction) through the first deposition assembly including the patterning slit sheet 130R spaced apart from the substrate 2 by a set or predetermined distance, the red emission layer 63R having an integrated shape is formed on the substrate 2 with respect to the pixels P1 through P5 along the direction (e.g., Y-axis direction) as shown in FIG. 5. By depositing the green and blue emission layers 63G and 63B by using deposition assemblies including patterning slit sheets having the similar shape as the patterning slit sheet 130R of the first deposition assembly, the green emission layer 63G and the blue emission layer 63B having integrated shapes may be formed on the substrate 2 with respect to the pixels P1 through P5 along the direction (e.g., Y-axis direction).

Here, as described above, since the patterning slit sheet 130R does not include a patterning slit in the region corresponding to the space between the pixels in the second direction (e.g., X-axis direction), an emission layer may not be formed on the bus electrode 64 between the adjacent pixels (for example, pixels P1 and P6) in the second direction (e.g., X-axis direction) and extending in the first direction (e.g., Y-axis direction). Accordingly, an emission layer is not disposed between the bus electrode 64 and the counter electrode 62, and thus the bus electrode 64 contacts the counter electrode 62, thereby reducing the voltage drop of the counter electrode 62.

Meanwhile, the intermediate layer 63 of the OLED included in each sub-pixel of the organic light-emitting display device may include layers other than the emission layer, such as a hole injection layer (HIL), a hole transport layer (HTL), an electron transport layer (ETL), and an electron injection layer (EIL). Since the other layers do not emit light, the other layers have an integrated shape throughout an entire surface of a substrate in a general organic light-emitting display device.

However, as described above, when the organic light-emitting display device includes the bus electrode 64 between the adjacent pixels (for example, the pixels P1 and P6) in the second direction (e.g., X-axis direction), the intermediate layer 63 may not be formed between the bus electrode 64 and the counter electrode 62. In other words, when the intermediate layer 63 is formed on the bus electrode 64, the bus electrode 64 is unable to contact the counter electrode 62 and thus unable to reduce the voltage drop of the counter electrode 62.

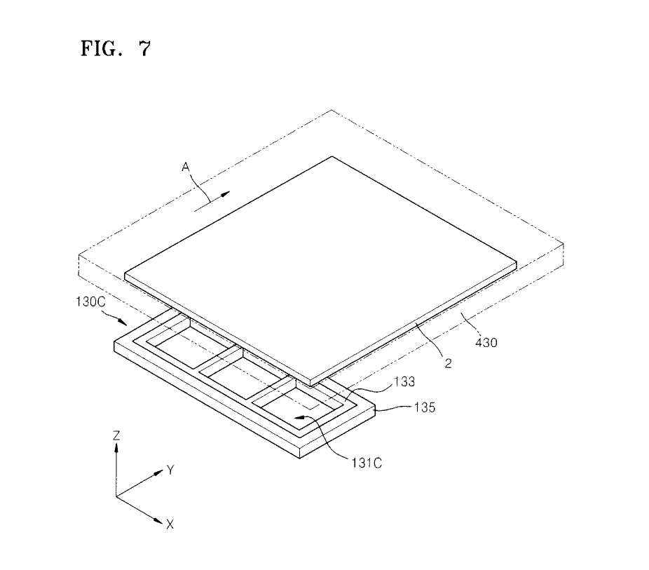

Accordingly, while depositing the layers (hereinafter, referred to as a first common layer for convenience of description) other than the emission layer in the intermediate layer 63, a patterning slit sheet 130C shown in FIG. 7 may be used. In more detail, FIG. 7 is a schematic perspective view of the substrate 2 on which a deposition material is to be deposited, and the patterning slit sheet 130C of a second deposition assembly from among the plurality of deposition assemblies in the deposition unit 100 of the deposition apparatus of FIG. 1, according to an embodiment of the present invention. The second deposition assembly may be used to deposit any one of a HIL, a HTL, an ETL, and an EIL on the substrate 2.

The patterning slit sheet 130C of the second deposition assembly includes patterning slits 131C corresponding to pixels, and does not include a patterning slit in a region corresponding to a space between pixels (for example, the pixels P1 and P6) in the second direction (e.g., X-axis direction).

When the first conveyer unit 410 conveys the transfer unit 430 to which the substrate 2 is fixed in one direction (e.g., +Y direction) through the second deposition assembly including the patterning slit sheet 130C spaced apart from the substrate 2 by a set or predetermined distance, the first common layer having an integrated shape is formed on the substrate 2 with respect to the pixels P1 through P5 along the direction (e.g., Y-axis direction).

Here, as described above, since the patterning slit sheet 130C of the second deposition assembly does not include a patterning slit in the region corresponding to the space between the pixels in the second direction (e.g., X-axis direction), the first common layer may not be formed on the bus electrode 64 arranged between the adjacent pixels (for example, the pixels P1 and P6) in the second direction (e.g., X-axis direction) and extending in the first direction (e.g., Y-axis direction). Accordingly, the first common layer is not arranged between the bus electrode 64 and the counter electrode 62, and thus the bus electrode 64 contacts the counter electrode 62, thereby reducing the voltage drop of the counter electrode 62.

Here, since the pattering slit sheet 130C includes the patterning slits 131C corresponding to the pixels, the first common layer may have an integrated shape throughout a plurality of sub-pixels, unlike the emission layer.

By forming an intermediate layer by using a deposition apparatus having first and second deposition assemblies having such structures, a counter electrode and a bus electrode definitely contact each other. Accordingly, an organic light-emitting display device, wherein a voltage drop of the counter electrode is reduced, may be manufactured.

FIGS. 5 through 7 are conceptually illustrated for convenience, and a width of each sub-pixel in the second direction (e.g., X-axis direction) may actually be very small. Accordingly, in FIG. 7, the patterning slit 131c of the patterning slit sheet 130C of the second deposition assembly is shown to have a shape close to a square, but the patterning slit 131C may actually have a shape extending in the first direction (e.g., Y-axis direction). The patterning slit 131R of the patterning slit sheet 130R of the first deposition assembly may have a shape extending in the first direction (e.g., Y-axis direction) as shown in FIG. 6.

The deposition apparatus has been mainly described with respect to one embodiment, but embodiments of the present invention are not limited thereto. For example, a method of manufacturing an organic light-emitting display device using the deposition apparatus is also within a scope of the present invention.

In a method of manufacturing an organic light-emitting display device, according to an embodiment of the present invention, an organic light-emitting display device including pixels each including n sub-pixels ,and an intermediate layer that is integrally formed throughout the n sub-pixels in a first direction may be manufactured.

For example, while the substrate 2 is fixed to the transfer unit 430, the transfer unit 430 may be conveyed into the chamber 101 by using the first conveyer unit 410 provided to penetrate through the chamber 101, and then while the deposition assembly 100-1 and the substrate 2 are spaced apart from each other in the chamber 101, the first conveyer unit 410 may convey the substrate 2 relatively to the deposition assembly 100-1 and form a layer by depositing a deposition material discharged from the deposition assembly 100-1 on the substrate 2. Next, the transfer unit 430 from which the substrate 2 is separated is returned by using the second conveyer unit 420 provided to penetrate through the chamber 101, and then the transfer unit 430 may be cyclically conveyed by the first and second conveyer units 410 and 420.

According to such a method, a deposition assembly may be a structure described with reference to the deposition apparatus 100 above. In this case, the forming of the layer may be divided into forming of an emission layer and forming of a common layer other than the emission layer.

The emission layer may be formed by depositing a deposition material discharged from the first deposition assembly on the substrate 2, wherein the first deposition assembly includes the patterning slits 131R corresponding to the sub-pixels emitting light in the first wavelength band from among the n sub-pixels of each pixel, and does not include a patterning slit in the region corresponding to the space between the pixels in the second direction (e.g., X-axis direction) crossing the first direction (e.g., Y-axis direction) and parallel to the substrate 2 fixed to the transfer unit 430.

Accordingly, the emission layer that corresponds to the sub-pixels emitting light in the first wavelength band, but does not correspond to the space between the pixels in the second direction may be formed. Emission layers may be formed in sub-pixels emitting light in other wavelength bands may be formed in the similar manner.

Also, the common layer may be formed by depositing a deposition material discharged from the second deposition assembly on the substrate 2, wherein the second deposition assembly includes the patterning slit sheet 130C including the patterning slits 131C corresponding to pixels, and does not include a patterning slit in the region corresponding to the space between pixels in the second direction (e.g., X-axis direction). Accordingly, the common layer may be integrally formed throughout the n sub-pixels of each pixel and throughout the pixels in the first direction (e.g., Y-axis direction), but may not correspond to the space between the pixels in the second direction (e.g., X-axis direction).

By forming an emission layer and a common layer as such, an organic light-emitting display device, wherein a voltage drop of a counter electrode is remarkably reduced, may be effectively manufactured by using a deposition apparatus having a small size, since an intermediate layer is not arranged between a bus electrode and the counter electrode such that the bus electrode and the counter electrode directly contact each other.

FIG. 8 is a schematic cross-sectional view of an organic light-emitting display device manufactured by using a deposition unit, such as the deposition unit 100 of FIG. 1, according to an embodiment of the present invention.

Referring to FIG. 8, various components of the organic light-emitting display device are formed on the substrate 2. Here, the substrate 2 may be the substrate 2 of FIG. 3, or a cut portion of the substrate 2. The substrate 2 may be formed of a transparent material, such as glass, plastic, or metal.

A common layer, such as a buffer layer 51, a gate insulation film 53, and an interlayer insulation film 55 may be formed on an entire surface of the substrate 2, a patterned semiconductor layer 52 including a channel region 52a, a source contact region 52b, and a drain contact region 52c may be formed on the substrate 2, and a gate electrode 54, a source electrode 56, and a drain electrode 57, which are components of a thin-film transistor TFT may be formed with the patterned semiconductor layer 52.

A passivation film 58 covering the TFT, and a planarization film 59 on the passivation film 58 and having a flat top surface may be formed on the entire surface of the substrate 2. The OLED may be arranged on the planarization film 59, wherein the OLED includes the pixel electrode 61 that is patterned, the counter electrode 62 approximately facing the pixel electrode 61, and the intermediate layer 63 between the pixel electrode 61 and the counter electrode 62 and having a multi-layer structure including the emission layer. As shown in FIG. 8, the intermediate layer 63 may include the red emission layer 63R, the green emission layer 63G, and the blue emission layer 63B, which are patterned to correspond to the pixel electrode 61, and may further include a first common layer 63C1 or a second common layer 63C2, which is integrally formed with respect to a red sub-pixel Sub_{R}, a green sub-pixel Sub_{G}, and a blue sub-pixel Sub_{B} included in the pixel P6.

The pixel electrode 61 may be electrically connected to the TFT through a via hole. Also, a pixel-defining film 60 having an opening defining each pixel region and covering an edge of the pixel electrode 61 may be formed on the planarization film 59 to approximately correspond to the entire surface of the substrate 2. The bus electrode 64 may be formed on the planarization film 59 with the same material as the pixel electrode 61 while forming the pixel electrode 61. The bus electrode 64 is not arranged between sub-pixels of a pixel, but may be arranged between pixels in the second direction (e.g., X-axis direction).

At least some components of the organic light-emitting display device may be formed by using the deposition apparatus described above.

For example, the intermediate layer 63 may be formed by using the deposition apparatus. For example, the red emission layer 63R, the green emission layer 63G, or the blue emission layer 63B of the intermediate layer 63 may be formed by using the first deposition assembly including the patterning slit sheet 130R of FIG. 6 or a patterning slit sheet having a similar shape, and the first common layer 63C1 or the second common layer 63C2 of the intermediate layer 63 may be formed by using the second deposition assembly including the patterning slit sheet 130C of FIG. 7. Here, the first or second common layer 63C1 or 63C2 may include any one of an HIL, a HTL, an ETL, or an EIL. The intermediate layer 63 formed as such may have a linear pattern.

The organic light-emitting display device of FIG. 8 may have a structure wherein sub-pixels emitting light in the same wavelength band are arranged in the first direction (e.g., Y-axis direction), and n sub-pixels (for example, three sub-pixels of a red sub-pixel, a green sub-pixel, and a blue sub-pixel) of each pixel are arranged in the second direction (e.g., X-axis direction) crossing the first direction. In addition, the organic light-emitting display device may include the bus electrodes 64 arranged between pixels in the second direction, extending in the first direction, and electrically connected to the counter electrode 62.

Here, the layers other than the emission layer included in the intermediate layer 63, i.e., the first and second common layers 63C1 and 63C2, may be integrally formed with respect to the red, green, and blue sub-pixels Sub_{R}, Sub_{G}, and Sub_{B} of each pixel, may be integrally formed throughout the pixels in the first direction (e.g., Y-axis direction), and may not contact the bus electrodes 64. As such, since the intermediate layer 63 is not arranged between the counter electrode 62 and the bus electrode 64, a degree where the voltage drop of the counter electrode 62 is generated may be effectively reduced by the bus electrode 64.

Moreover, as described above, the deposition apparatus of FIG. 1 may perform a deposition process on a set or predetermined region of a large substrate. For example, even when an organic light-emitting display device has a substrate having a size equal to or larger than 40 inches, the intermediate layer 63 may be accurately formed, thereby realizing an organic light-emitting display device having a high quality.

The deposition apparatus, wherein a common layer of an intermediate layer is integrally formed with respect to sub-pixels of each pixel, the method of manufacturing an organic light-emitting display device, and the organic light-emitting display device manufactured by using the method have been described above, but an embodiment of the present invention is not limited thereto. In other words, the common layer may be called a common layer as layers are formed of the same material with respect to sub-pixels, but alternatively, the common layers may be formed by patterned to be spaced apart from each other according to sub-pixels without being integrally formed throughout sub-pixels in one pixel.

For example, a patterning slit sheet of a second deposition assembly for depositing a common layer from among a plurality of deposition assemblies included in the deposition apparatus may include patterning slits corresponding to n sub-pixels of each pixel and may not include a patterning slit in a region corresponding to spaces between pixels in a second direction (e.g., X-axis direction) and between the n sub-pixels. A difference between such a patterning slit sheet and the patterning slit sheet 130R of FIG. 6 is that when each pixel has a red sub-pixel, a green sub-pixel, and a blue sub-pixel, the patterning slit sheet of the second deposition assembly for depositing the common layer includes a patterning slit corresponding to each of the red sub-pixel, the green sub-pixel, and the blue sub-pixel. The patterning slit sheet 130R of FIG. 6 has the patterning slit 131R corresponding only to the red sub-pixel.

According to a method of manufacturing an organic light-emitting display device by using the deposition apparatus, a layer is formed by depositing a deposition material discharged from a second deposition assembly including a patterning slit sheet that includes patterning slits corresponding to n sub-pixels of each pixel and does not include a patterning slit in a region corresponding to spaces between pixels in a second direction (e.g., X-axis direction) and between the n sub-pixels, while forming a common layer.

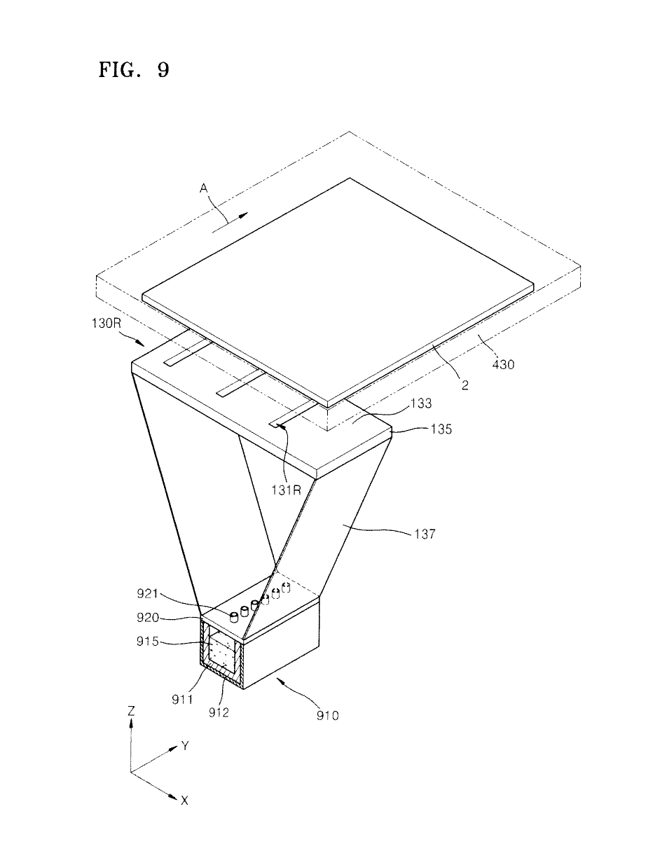

Meanwhile, in the deposition apparatus described above with reference to FIG. 3, the first and second deposition source nozzle units 120a and 120b include the plurality of deposition source nozzles 121 arranged in the second direction (for example, X-axis direction) crossing the first direction (e.g., +Y direction) and parallel to the substrate 2 fixed to the transfer unit 430. However, according to another embodiment, a plurality of deposition source nozzles 921 of a deposition source nozzle unit 920 may be arranged along the first direction (e.g., +Y direction) as shown in FIG. 9. FIG. 9 is a schematic perspective view of a part of a deposition assembly of a deposition apparatus according to another embodiment of the present invention.

When patterned layers extending in the first direction (e.g., +Y-axis direction) and spaced apart from each other in the second direction (e.g., X-axis direction) are formed on the substrate 2 by using the deposition apparatus, the deposition source nozzle unit 920 may include the deposition source nozzles 921 arranged along the first direction (e.g., +Y direction) as shown in FIG. 9 so that one deposition source nozzle 921 is located along the second direction (for example, X-axis direction) crossing the first direction (+Y direction) and parallel to the substrate 2 fixed to the transfer unit 430, on a plane (e.g., ZX plane) perpendicular to the first direction. Accordingly, generation of a shadow may be remarkably reduced while forming a patterned layer.

As shown in FIG. 9, a deposition material located in a crucible 911 of a deposition source 910 may be evaporated by a heater 912, discharged through the deposition source nozzle 921 of the deposition source nozzle unit 920, and deposited on the substrate 2 through a patterning slit 131R of the patterning slit sheet 130R. Here, the deposition source 910 and/or the deposition source nozzle unit 920, and the pattering slit sheet 130R may be combined to each other by a connecting member 137.

As described above, the one or more embodiments of the present invention provide methods of manufacturing organic light-emitting display devices, wherein a voltage drop of a counter electrode is effectively reduced, and organic light-emitting display devices manufactured by the method. However, the scope of the present invention is not limited by these effects.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A method of manufacturing an organic light-emitting display device comprising pixels, each of the pixels comprising n sub-pixels, the organic light-emitting display device comprising an intermediate layer integrally formed throughout a plurality of sub-pixels in a first direction, the method comprising:
conveying a transfer unit into a chamber by using a first conveyer unit configured to pass through the chamber, while a substrate is fixed to the transfer unit;
forming a layer by depositing a deposition material discharged from a plurality of deposition assemblies while conveying one of the substrate or the plurality of deposition assemblies relative to the other by using the first conveyer unit, while the substrate is spaced apart from the plurality of deposition assemblies by a distance, the plurality of deposition assemblies being arranged in the chamber; and
returning the transfer unit from which the substrate is separated, by using a second conveyer unit,
wherein each of the plurality of deposition assemblies comprises:
a deposition source for discharging the deposition material;
a deposition source nozzle unit of the deposition source arranged in a direction of the first conveyer unit and comprising a deposition source nozzle; and
a patterning slit sheet facing the deposition source nozzle unit and comprising a plurality of patterning slits arranged along one direction, and
wherein the forming of the layer comprises:
forming a layer by depositing a deposition material discharged from a first deposition assembly on the substrate, wherein the first deposition assembly comprises a patterning slit sheet that comprises patterning slits corresponding to sub-pixels emitting light in a first wavelength band from among the n sub-pixels of each of the pixels and does not comprise a patterning slit in regions corresponding to spaces between the pixels in a second direction crossing the first direction and parallel to the substrate fixed to the transfer unit; and
forming a layer by depositing a deposition material discharged from a second deposition assembly on the substrate, wherein the second deposition assembly comprises a patterning slit sheet that comprises patterning slits corresponding to the pixels and does not comprise a patterning slit in regions corresponding to spaces between the pixels in the second direction.

2. The method of claim 1, wherein the one direction is the second direction.

3. The method of claim 2, wherein the patterning slits of the patterning slit sheets of the first and second deposition assemblies extend in the first direction.

4. A method of manufacturing an organic light-emitting display device comprising pixels, each of the pixels comprising n sub-pixels, the organic light-emitting display device comprising an intermediate layer integrally formed throughout a plurality of sub-pixels in a first direction, the method comprising:
conveying a transfer unit into a chamber by using a first conveyer unit configured to penetrate through the chamber, while a substrate is fixed to the transfer unit;
forming a layer by depositing a deposition material discharged from a plurality of deposition assemblies while conveying one of the substrate or the plurality of deposition assemblies relative to the other by using the first conveyer unit, while the substrate is spaced apart from the plurality of deposition assemblies by a distance, the plurality of deposition assemblies being arranged in the chamber; and
returning the transfer unit from which the substrate is separated, by using a second conveyer unit,
wherein each of the plurality of deposition assemblies comprises:
a deposition source for discharging the deposition material;
a deposition source nozzle unit of the deposition source arranged in a direction of the first conveyer unit and comprising a deposition source nozzle; and
a patterning slit sheet facing the deposition source nozzle unit and comprising a plurality of patterning slits arranged along one direction, and
wherein the forming of the layer comprises:
forming a layer by depositing a deposition material discharged from a first deposition assembly on the substrate, wherein the first deposition assembly comprises a patterning slit sheet that comprises patterning slits corresponding to sub-pixels emitting light in a first wavelength band from among the n sub-pixels of each of the pixels and does not comprise a patterning slit in regions corresponding to spaces between the pixels in a second direction crossing the first direction and parallel to the substrate fixed to the transfer unit; and
forming a layer by depositing a deposition material discharged from a second deposition assembly on the substrate, wherein the second deposition assembly comprises a patterning slit sheet that comprises patterning slits corresponding to the n sub-pixels of each of the pixels and does not comprise a patterning slit in regions corresponding to spaces between the pixels in the second direction and between the n sub-pixels in the second direction.

5. The method of claim 4, wherein the one direction is the second direction.

6. The method of claim 5, wherein the patterning slits of the patterning slit sheets of the first and second deposition assemblies extend in the first direction.

7. An organic light-emitting display device comprising:
a substrate;
a plurality of thin-film transistors on the substrate;
a plurality of pixel electrodes electrically connected to the plurality of thin-film transistors;
deposition layers on the plurality of pixel electrodes; and
a counter electrode on the deposition layers,
wherein at least two of the deposition layers have a linear pattern formed by using the method of claim 1.

8. The organic light-emitting display device of claim 7, further comprising pixels, each comprising n sub-pixels, wherein sub-pixels emitting light in a same wavelength band are arranged in the first direction, and the n sub-pixels of each of the pixels are arranged in the second direction crossing the first direction.

9. The organic light-emitting display device of claim 8, further comprising bus electrodes between each of the pixels in the second direction, extended in the first direction, and electrically connected to the counter electrode.

10. The organic light-emitting display device of claim 9, wherein the deposition layers comprise an emission layer, wherein layers of the deposition layers other than the emission layer are integrally formed through the n sub-pixels of each of the pixels, are integrally formed through the pixels in the first direction, and do not contact the bus electrodes.

11. The organic light-emitting display device of claim 9, wherein the deposition layers comprise an emission layer, wherein layers of the deposition layers other than the emission layer are not formed between the n sub-pixels in the second direction of each of the pixels, are integrally formed through sub-pixels emitting light in a same wavelength band in the first direction, and do not contact the bus electrodes.

12. The organic light-emitting display device of claim 7, wherein the substrate has a size equal to or larger than 40 inches.

13. An organic light-emitting display device comprising:
a substrate;
a plurality of thin-film transistors on the substrate;
a plurality of pixel electrodes electrically connected to the plurality of thin-film transistors;
deposition layers on the plurality of pixel electrodes; and
a counter electrode on the deposition layers,
wherein at least two of the deposition layers have a linear pattern formed by using the method of claim 4.

14. The organic light-emitting display device of claim 13, further comprising pixels, each comprising n sub-pixels, wherein sub-pixels emitting light in a same wavelength band are arranged in the first direction, and the n sub-pixels of each of the pixels are arranged in the second direction crossing the first direction.

15. The organic light-emitting display device of claim 14, further comprising bus electrodes between each of the pixels in the second direction, extended in the first direction, and electrically connected to the counter electrode.

16. The organic light-emitting display device of claim 15, wherein the deposition layers comprise an emission layer, wherein layers of the deposition layers other than the emission layer are integrally formed through the n sub-pixels of each of the pixels, are integrally formed through the pixels in the first direction, and do not contact the bus electrodes.

17. The organic light-emitting display device of claim 15, wherein the deposition layers comprise an emission layer, wherein layers of the deposition layers other than the emission layer are not formed between the n sub-pixels in the second direction of each of the pixels, are integrally formed through sub-pixels emitting light in a same wavelength band in the first direction, and do not contact the bus electrodes.

18. The organic light-emitting display device of claim 13, wherein the substrate has a size equal to or larger than 40 inches.
